(19) United States
(12) Patent Application Publication
(10) Pub. No.: US 2021/0178606 A1
(43) Pub. Date: Jun. 17, 2021

(54) APPARATUS HAVING A CAPACITIVE SENSING SYSTEM AND ELECTRIC LINE(S)

(71) Applicant: FOGALE NANOTECH, Nîmes (FR)

(72) Inventors: Yacine CHAKOUR, Sernhac (FR); Didier ROZIERE, Nîmes (FR); Alain COURTEVILLE, Congenies (FR)

(21) Appl. No.: 17/257,170

(22) PCT Filed: Jul. 4, 2019
(86) PCT No.: PCT/EP2019/067952

§ 371 Date: Dec. 30, 2020

(30) Foreign Application Priority Data
Jul. 18, 2018 (FR) 1856647

(51) Int. Cl. B25J 13/08; B25J 19/00; B25J 19/06

(52) U.S. Cl. CPC B25J 13/086; B25J 19/06; B25J 19/0025

(57) ABSTRACT

An appliance includes:
at least one capacitive measurement electrode;
at least one capacitive detection electronics; and
an electric line, having at least one electric wire, in the detection zone;
   the appliance also having at least one spacer structure for distancing the electric line between:
a minimum distance (Dₘᵢₙ) corresponding to the distance beyond which a reference electric line generates a coupling capacitance with the at least one measurement electrode, less than a predetermined threshold capacitance; and
a maximum distance (Dₘₐₓ) corresponding to the distance beyond which a reference object generates a coupling capacitance with the at least one measurement electrode, less than the threshold capacitance.

### TECHNICAL FIELD

The present invention relates to an appliance, such as a robot, equipped with capacitive detection of object(s) and at least one electric line.

The field of the invention is, non-limitatively, that of the field of robotics, in particular the field of industrial robotics or service robots, for example medical or domestic, or also collaborative robots, also called “cobots”.

### STATE OF THE ART

In the field of collaborative robotics, the robots can be equipped with capacitive sensors in order to detect the approach of objects or human operators in the vicinity of said robot. These sensors can for example comprise capacitive electrodes arranged in the form of sensitive surfaces that cover the surface of the robot at least partially. These capacitive electrodes are polarized at an alternating excitation potential, and connected to detection electronics that measures the capacitive coupling between these electrodes and objects polarized at a potential different from the electrodes, most usually ground.

These robots are generally equipped with tools or accessories, referenced to ground, and connected to control electronics or electric power supplies by electric cables that pass the length of the robot in cable runs.

When these cables are in proximity to a surface of capacitive sensors, they may be detected as obstacles and mistakenly trigger safety procedures. These cables can also interfere with the operation of the capacitive sensors in terms of accuracy and detection reach.

A solution may be to distance these cables so that they are outside of the detection zone of the capacitive sensors. But this solution risks collision between an object and said cables.

A purpose of the present invention is to overcome these drawbacks.

Another purpose of the invention is to propose a solution allowing the passage of a cable polarized at a potential different from the potential of a capacitive sensor in proximity to said capacitive sensor without interfering with the operation of said capacitive sensor.

It is also a purpose of the present invention to propose a solution allowing the passage of a cable polarized at a potential different from the potential of a capacitive sensor in proximity to said capacitive sensor without risk of collision with the neighbouring objects.

### DISCLOSURE OF THE INVENTION

At least one of these purposes is achieved with an appliance comprising:
at least one electrode, called measurement electrode, polarized at an alternating electrical potential, called detection electrical potential, different from a ground potential, at a frequency, called detection frequency, in order to detect at least one object in a detection zone,
at least one capacitive detection electronics, connected to said measurement electrodes, in order to detect a signal with respect to a capacitive coupling between said object and at least one measurement electrode, and
an electric line comprising at least one electric wire, in said detection zone.

The appliance according to the invention also comprises at least one spacing means for distancing said electric line in order to position it at a distance from the at least one measurement electrode comprised between:
a distance, called minimum distance, corresponding to the distance beyond which an electric line, called reference electric line, with a predetermined dimension, generates a coupling capacitance with the at least one measurement electrode, less than a predetermined threshold capacitance; and
a distance, called maximum distance, corresponding to the distance beyond which an object, called reference object, with a predetermined dimension, greater than the dimension of said reference electric line, generates a coupling capacitance with the at least one measurement electrode less than said threshold capacitance.

In other words, the invention proposes to:
choose a reference electric line with a predetermined dimension, and a reference object with a predetermined dimension greater than that of said reference electric line;
determine a distance, called minimum distance, starting from which the coupling capacitance between said reference electric line and the measurement electrode is less than the predetermined threshold capacitance; and
determine a distance, called maximum distance, starting from which the coupling capacitance between said reference object and the measurement electrode is less than the predetermined threshold capacitance.

Once the minimum distance and the maximum distance are determined, using a spacing means in order to position the electric line of the appliance between said minimum and maximum distances.

Thus, the device according to the invention proposes a specific positioning of the electric line with respect to the capacitive measurement electrodes. As a result, the device according to the invention makes it possible to avoid interferences, or detection errors, caused by the detection of the electric line by the measurement sensors. At the same time, the device according to the invention makes it possible to avoid the risks of collision between the electric line and the neighbouring objects since these objects themselves are detected when they approach the electric line.

In the present application, two alternating potentials are identical at a given frequency when they each comprise an identical or similar alternating component at said frequency; i.e. having the same amplitude (for example plus or minus a few percentage points) and the same phase (for example plus or minus a few degrees). Thus, the at least one of the two potentials identical at said frequency can also comprise a continuous component, and/or an alternating component having a frequency different from said given frequency.

Similarly, two alternating potentials are different at the given frequency when they do not have an identical or similar alternating component at this given frequency.

In the present application, the term “ground potential” or “general ground potential” denotes a reference potential of the electronics, of the appliance or of its environment, which can be for example an electrical ground. This ground potential can correspond to an earth potential or to another potential, connected or not to the earth potential.

Furthermore it is noted that generally, objects which are not in direct electrical contact with a particular electrical potential (electrically floating objects) tend to polarize by capacitive coupling at the electrical potential of other objects present in their environment, such as for example earth or electrodes, if the surface areas of overlap between these objects and those of the environment (or the electrodes) are sufficiently large.

In the present application, by “object” is meant any object or any person that may be located within the environment of the appliance.

Preferentially, the threshold capacitance can be determined by taking account of:
a capacitance detection limit, dependent on a detection noise level of the capacitive detection electronics; and/or
an infinite capacitance, such as measured by the capacitive detection electronics in the absence of an object or electric line.

The infinite capacitance is the capacitance which exists between the electrodes and the environment, due to the presence of the electric charges in the electrode, and any elements of the environment. It thus corresponds to an asymptotic limit of the detection. It can also be variable as a function of the configuration or the position of the appliance on which the electrodes are positioned. In this case, the threshold capacitance can be determined by taking account of an infinite capacitance in a particular configuration of the appliance and/or its environment.

The detection noise level can take account, in particular, of electronic noises and gain and offset instabilities.

The capacitance detection limit can be determined starting from this detection noise level, and an acceptable signal to noise ratio. The capacitance detection limit can for example correspond to 10 times the detection noise level.

In general, the threshold capacitance can be defined as a capacitance, as measured by the capacitive detection electronics, starting from which it is considered that a distinct object in the environment of the appliance is present and detected. Conversely, it is thus possible to consider that no object is present when the capacitance measured is less than this threshold capacitance.

Non-limitatively, this threshold capacitance can be defined as, or starting from, an infinite capacitance, increased by the capacitance detection limit, or a quantity dependent on a detection noise level of the capacitive detection electronics.

Thus, any electric line with dimension less than or equal to that of the reference electric line, is no longer detected when it is beyond the minimum distance. In addition, any object with dimension greater than or equal to that of the reference object, is detected when it is located below the maximum distance.

Consequently, in the distance interval comprised between the minimum distance and the maximum distance:
any electric line with dimension equal to or less than that of the reference line is not detected; while
any object with dimension equal to or greater than that of the reference object is detected.

Advantageously, the dimension of the reference electric line can correspond to a total diameter of the conductors of said reference line.

This total diameter can be defined as the diameter of a circle encompassing all of the conductors of the line.

Thus, the total diameter of the reference electric line used for the calculations must be chosen so that the diameter, or the total diameter, of the electric line used in the appliance in practice is less than the total diameter of said reference electric line. Or conversely, the electric line used in the appliance must have a total diameter less than or equal to the total diameter of the reference electric line.

The dimension of the reference object can correspond to:
a width or a length of the reference object; or
a width or a length of a reference object, optionally fictitious, of the same width or the same length as the at least one measurement electrode.

The second condition can correspond to the fact that the dimension to be taken into account in order to determine a coupling capacitance between a reference object and an electrode is the smaller of the two dimensions, which corresponds to the overlap of the surfaces.

As explained above, the maximum positioning distance of the electric line, denoted Dₘₐₓ, corresponds in fact to the upper boundary of the detection zone of the measurement electrodes, which is defined as the maximum distance at which a reference object, or a reference operator, with a minimum surface area, denoted S_{min,o}, could be detected in air by the measurement electrodes, and thus generate a threshold capacitance, denoted Cₘᵢₙ, corresponding, for example, to the minimum capacitance exploitable by the detection electronics, in the sense of the noise threshold or the infinite capacitance as previously described.

This maximum distance Dₘₐₓ is evaluated with a dielectric of the air type (εᵣ=1), which is the least favourable condition.

The reference object can be for example a hand. The minimum surface area S_{min,o} can be defined as the overlap surface area between a measurement electrode and the reference object.

The minimum positioning distance of the line, denoted Dₘᵢₙ, corresponds to the distance starting from which the reference electric line starts to be detected by the measurement electrodes. This is produced when the electrode-line capacitance, denoted Cₑₗ, is equal to the minimum capacitance Cₘᵢₙ.

Insofar as the reference electric line can be surrounded by sheaths and especially fixed on fixing elements, it is possible to

take account of a relative permittivity εᵣ in calculating the coupling capacitance of the electric line Cₑₗ. Thus:

Cₑₗ=Cₘᵢₙ (1)

I.e. by replacing Cₑₗ and Cₘᵢₙ with their respective expressions according to the parallel-plate capacitor formula:

$$\frac{{ɛ}_{0} {ɛ}_{r} {S}_{min , c}}{{D}_{min}} = \frac{{ɛ}_{0} {S}_{min , o}}{{D}_{max}} \qquad ( 2 )$$

where S_{min,c} is the overlap surface area between the reference electric line and the measurement electrode. Thus:

$${D}_{min} = \frac{{ɛ}_{r} {S}_{min , c}}{{S}_{min , o}} {D}_{max} \qquad ( 3 )$$

is obtained.

Thus, a spacing distance of the reference electric line, denoted D, with respect to the measurement electrode:

$$\frac{{ɛ}_{r} {S}_{min , c}}{{S}_{min , o}} {D}_{max} < D < {D}_{max} \qquad ( 4 )$$

is obtained.

The minimum positioning distance of the line Dₘᵢₙ thus depends on the relationship of the surfaces of the reference electric line and of the reference object, and on the relative dielectric permittivity between the reference electric line and the measurement electrodes.

In practice, the following approximations can be made:
the measurement electrodes can be rectangular or square with a dimension (width or length) of the order of 50 mm or 70 mm;
the reference object can correspond to a hand of an operator, for example of dimension (width) 90 to 100 mm; and
the electric lines used have a diameter (or an equivalent total diameter taking account of the curvature of the lines of the dielectric fields) of the order of 2 to 10 mm.

It is thus possible to assume, without too much loss of generality, that the reference object, the reference electric line and the measurement electrode can be approximated by rectangular shapes. It is also possible to assume that the reference object and the reference electric line are both larger than the measurement electrode in one dimension, for example the length.

With all of these approximations, and non-limitatively, the minimum distance and the maximum distance can be chosen in order to verify the following relationship:

$${D}_{min} = \frac{{ɛ}_{r} {L}_{c}}{{L}_{o}} {D}_{max} \qquad ( 5 )$$

with:
Dₘᵢₙ the minimum distance,
Dₘₐₓ the maximum distance,
εᵣ the overall (or average) relative permittivity of the spacing means,
L_{c} the dimension of the reference electric line, and
Lₒ the dimension of the reference object.

At least one spacing means can be produced by any manufacturing method, and in particular by moulding, injection, machining, 3D printing etc.

Preferentially, at least one spacing means can have an overall (or average) relative dielectric permittivity less than or equal to 2, in particular 1.5.

Thus, the influence of the spacing means on the capacitive detection is reduced, or even insignificant, and it is possible to minimize the minimum distance Dₘᵢₙ.

The spacing means can for example be produced from, or comprise, at least one dielectric material such as plastic, a polymer (polyvinyl chloride PVC, polyurethane, polyester, polyamide, acrylonitrile butadiene styrene ABS, etc.), or also wood, glass.

At least one spacing means can be fixed to a surface of the appliance according to the invention, in particular to an external surface of said appliance.

Alternatively, or in addition, at least one spacing means can be fixed to the electric line, and in particular around the electric line.

In addition, at least one spacing means can extend only or essentially between the appliance according to the invention and the electric line.

Consequently, the spacing means is located entirely between the electric line and the appliance according to the invention, with the optional exception of a fixing element or a strap around the cable.

Alternatively, or in addition, at least one spacing means can extend beyond the electric line, seen from the at least one measurement electrode.

Thus, such a spacing means makes it possible to constitute a contact surface that is beyond the electric line, so that it protects the electric line against impacts with external objects or surfaces, and/or conversely, that it protects objects from a direct contact with the electric line.

According to a particularly advantageously characteristic, the height of at least one spacing means can be adjustable and/or variable.

Thus it is possible to adapt, in particular on the fly, to different dimensions of electric lines, in the case for example of modification, addition, removal or replacement of an electric line.

At least one spacing means can be rigid.

Alternatively or in addition, at least one spacing means can be flexible.

Such a spacing means makes it possible to avoid damaging the electric line or the appliance when the appliance comprises an articulated part along which the electric line extends.

In fact, changing the position, and in particular the orientation of such an articulated part, can cause the spacing to vary between the electric line and said articulated part. The fact of using a flexible spacing means allows these spacing variations to be accommodated without damaging the electric line.

Such a situation can occur, in particular, when the appliance according to the invention is a robotized arm comprising articulated segments.

Moreover, the flexibility makes it possible to absorb or to minimize impacts with objects in the case of direct contact with the electric line or the spacing means.

In particular, at least one spacing means can be flexible and extend beyond the electric line, seen from the at least one measurement electrode.

This configuration makes it possible to absorb or minimize impacts with objects in the case of direct contact with the spacing means. It can also make it possible to generate a movement of the electric line, in the case of pressure, towards the measurement electrodes so that this line becomes detectable and thus makes it possible to detect the pressure.

Advantageously, at least one spacing means can be inflatable, and/or have the form of a cylindrical brush with radial bristles and/or, at least partly, hollow or spongy, or in the form of a foam.

Such a spacing means has in particular a reduced relative dielectric permittivity due to a high proportion of air in the volume.

The appliance according to the invention can also comprise at least one electrode, called guard electrode, arranged on the side opposite the detection zone with respect to the measurement electrodes, and polarized at a potential, called guard potential, that is identical to the detection potential at the detection frequency.

Such at least one guard electrode makes it possible to protect the measurement electrode or electrodes against the leakage capacitances or unwanted coupling, or interferences, that can be caused by parts of the appliance, which may not be at the detection potential, at the detection frequency. Thus, the range and the accuracy of the capacitive detection are improved.

The guard electrode or electrodes can be placed under the measurement electrode or electrodes, on the opposite side to the detection zone.

The capacitive detection implemented in the appliance according to the invention is based on the measurement/detection of a capacitive coupling signal between at least one measurement electrode and the object to be detected.

To this end, the capacitive detection electronics can comprise measurement electronics for, on the one hand:
supplying the detection potential, and the guard potential if required, at the detection frequency; and
measuring/detecting a signal with respect to the electrode-object coupling.

According to an embodiment, the measurement electronics can comprise an operational amplifier (OA), or a circuit producing an operational amplifier, functioning as a transimpedance or charge amplifier, in which:
a first input, for example an inverting input, is connected to one or more measurement electrodes, directly or via an optional polling means for example;
a second input, for example a non-inverting input, is connected to an oscillator supplying the detection potential and the guard potential; and
the output is looped on said first input via an impedance, and in particular via a capacitor.

In this configuration, the output of the OA supplies a voltage Vₛ, the amplitude of which is proportional to the electrode-object capacitance, denoted Cₑₒ, between at least one measurement electrode and the object.

The output of the operational amplifier can be connected, directly or indirectly, to a module for measuring the voltage Vₛ. This module for measuring the voltage Vₛ can comprise a signal conditioner, a demodulation such as a synchronous demodulation at the detection frequency, or an amplitude detection.

The detection electronics can also comprise an oscillator supplying the alternating detection potential and the guard potential if required.

Advantageously, the detection electronics can be at least partially electrically referenced to the detection potential.

The detection electronics can also comprise at least one calculation module arranged in order to determine a distance or an item of distance information, and/or a contact or an item of contact information, between at least one measurement electrode and the object, as a function of the signal with respect to the coupling capacitance Cₑₒ originating from the signal conditioner.

This calculation module can for example comprise or be produced in the form of a microcontroller, or an FPGA.

The calculation module can also supply other items of information, such as triggering of alarms or safety procedures, when for example the measured distances are less than the predetermined distance thresholds.

Of course, the detection electronics can comprise components other than those described.

The detection electronics can be produced by digital components, or by analogue components, or even by a combination of digital components and analogue components.

In the appliance according to the invention, at least one electric line can be a line for the electric power supply of, and/or control of, and/or for communication with, an electric component part of said appliance.

The appliance according to the invention can have the form of a robot.

According to non-limitative embodiments, the robot can be or comprise any robotized system.

It can in particular have the form of, or comprise, for example a robotized arm, a mobile robot, a vehicle on wheels or tracks such as a truck equipped with an arm or a handling system, or a robot of the humanoid, gynoid or android type, optionally provided with movement component parts such as limbs.

In particular the appliance according to the invention can be a robot, in particular a robotized arm, comprising at least two segments connected together by an articulation, and comprising at least one spacing means at said articulation.

### DESCRIPTION OF THE FIGURES AND EMBODIMENTS

Other advantages and characteristics will become apparent on examination of the detailed description of non-limitative examples and from the attached drawings in which:

FIG. 1 is a diagrammatic representation of a non-limitative embodiment of capacitive detection electronics that can be utilized in an appliance according to the invention;

FIGS. 2-4 are diagrammatic representations of non-limitative examples of spacing means able to be used in an appliance according to the invention; and

FIG. 5 is a diagrammatic representation of an example of a device according to the invention.

It is well understood that the embodiments that will be described hereinafter are in no way limitative. In particular, variants of the invention may be envisaged comprising only a selection of characteristics described hereinafter, in isolation from the other characteristics described, if this selection of characteristics is sufficient to confer a technical advantage or to differentiate the invention with respect to the state of the prior art. This selection comprises at least one, preferably functional, characteristic without structural details, or with only a part of the structural details if this part alone is sufficient to confer a technical advantage or to differentiate the invention with respect to the state of the prior art.

In particular, all the variants and all the embodiments described may be combined together if there is no objection to such combination from a technical point of view.

In the figures, elements that are common to several figures retain the same reference.

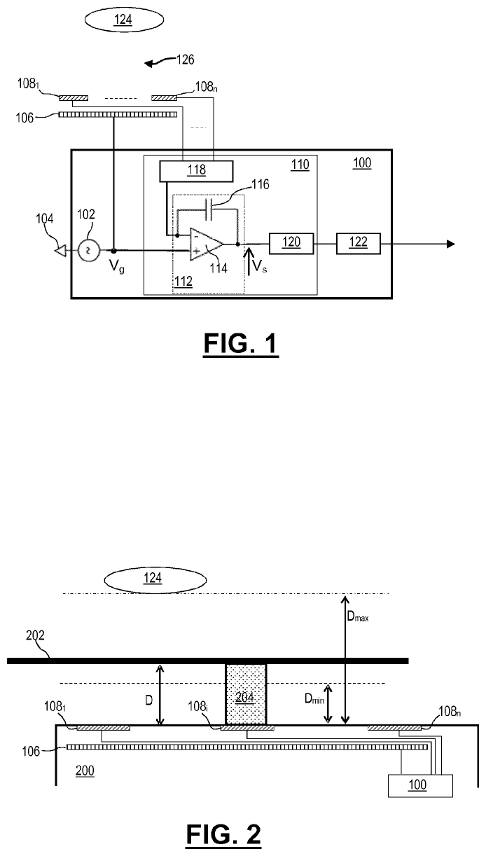

FIG. 1 is a diagrammatic representation of a non-limitative embodiment of capacitive detection electronics that can be utilized in an appliance according to the invention.

The detection electronics 100, shown in FIG. 1, can be produced in an analogue or digital form, or an analogue/digital combination.

The detection electronics 100 comprises an oscillator 102 delivering an alternating voltage, denoted V_{G}, and referenced to a ground potential 104.

The voltage V_{G} is used as guard potential in order to polarize one or more guard electrodes 106 via a line or several lines, and as excitation potential in order to polarize measurement electrodes 108₁-108ₙ, which may also be denoted by the reference 108, or the reference 108ᵢ, hereinafter. It can be any wave shape, for example sinusoidal or square, at a frequency or a fundamental frequency corresponding to the detection frequency.

The detection electronics 100 comprises a measurement electronics 110 in order to polarize the measurement electrodes 108 and measure a signal with respect to an electrode-object capacitance Cₑₒ between an object and at least one measurement electrode 108.

The measurement electronics 110 comprises a current, or charge, amplifier 112 represented by an operational amplifier (OA) 114 and a feedback capacitor 116 looping the output of the OA 114 at the inverting “−” input of the OA 114.

In addition, in the example shown, the non-inverting “+” input of the OA 114 receives the voltage V_{G} and the inverting “−” input of the OA 114 is provided in order to be connected to each measurement electrode 108, via a polling means 118, which can be for example a switch, so as to poll the measurement electrodes 108 individually in turn.

Use of the polling means 118 is of course optional.

Under these conditions, the charge amplifier 112, and in particular the OA 114, supplies at the output a voltage Vₛ of amplitude proportional to the coupling capacitance Cₑₒ between one or more measurement electrodes 108 connected at the “−” input thereof and an object in proximity, or in contact, with said measurement electrode 108.

The measurement electronics 110 can also comprise a signal conditioner 120 making it possible to obtain a signal representative of the sought coupling capacitance Cₑₒ. This signal conditioner 120 can comprise for example a synchronous demodulator for demodulating the signal with respect to a carrier, at the detection frequency. The signal conditioner 120 can also comprise an asynchronous demodulator or an amplitude detector. This signal conditioner 120 can of course be produced in an analogue and/or digital form (microprocessor), and comprise all necessary means for filtering, conversion, processing etc.

The signal conditioner 120 measures and supplies the value of the voltage Vₛ.

The detection electronics 100 can also comprise a calculation module 122 arranged in order to determine a distance or an item of distance information, and/or a contact or an item of contact information, between at least one measurement electrode 108 and an object, as a function of the signal with respect to the coupling capacitance Cₑₒ originating from the signal conditioner 120.

This calculation module 122 can for example comprise or be produced in the form of a microcontroller, or an FPGA.

The calculation module 122 can also supply other items of information, such as triggering of alarms or safety procedures, when for example the measured distances are less than predetermined distance thresholds.

Of course, the detection electronics 100 can comprise components other than those described.

The detection electronics 100, or at least its sensitive part with the charge amplifier 112, can be referenced (or supplied by electrical power supplies referenced) to the guard potential V_{G}, in order to minimize the parasitic capacitances.

The detection electronics 100 can also be referenced, more conventionally, to the ground potential 104.

Thus, when an object 124 enters the detection zone 126 of the measurement electrode or electrodes 108₁-108ₙ, this object 124 enters into capacitive coupling with at least one measurement electrode 108, which modifies the capacitance seen by this measurement electrode 108, and therefore the amplitude of the voltage Vₛ measured by the measurement electronics 110 connected to this measurement electrode 108.

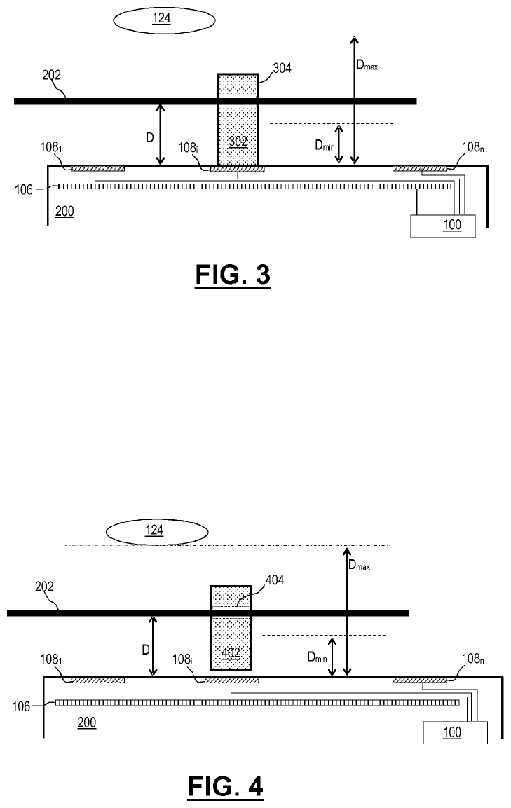

FIG. 2 is a diagrammatic representation of a non-limitative embodiment of an appliance according to the invention.

FIG. 2 shows, in a very partial manner, an appliance 200, which can be for example a robot.

The appliance 200 comprises measurement electrodes 108₁-108ₙ, a single guard electrode 106. Alternatively, the appliance 200 can comprise several guard electrodes.

The appliance 200 also comprises detection electronics, and in particular the detection electronics 100 in FIG. 1.

The appliance 200 is equipped with an electric line 202. The electric line 202 can for example be provided in order to supply, or communicate with, an electrical component part (not shown) of said appliance 200.

The appliance 200 is also equipped with a spacing means 204. The spacing means 204 has the function of separating the electric line 202, with respect to the measurement electrodes 108, by a distance D comprised between:
a minimum distance, denoted Dₘᵢₙ, beyond which a predetermined reference electric line, of diameter greater than the diameter of the electric line 202, is no longer detected by the measurement electrodes 108; and
a maximum distance, denoted Dₘₐₓ, beyond which a predetermined reference object, of dimensions smaller than the object 124, is no longer detected by the measurement electrodes 108.

As explained above, by taking approximations without too much loss of generality, the minimum and maximum distances are connected by the following relationship:

$${D}_{min} = \frac{{ɛ}_{r} {L}_{c}}{{L}_{o}} {D}_{max}$$

with:
εᵣ the relative permittivity of the spacing means 204,
L_{c} the dimension of the predetermined reference electric line, the diameter of which is greater than or equal to the diameter of the line 202, and
Lₒ the dimension of a reference object the smallest dimension of which is less than or equal to the smallest dimension of the object 124, or the dimension of the measurement electrodes 108, if this is smaller.

According to a non-limitative embodiment given by way of illustration only:
the reference object can be a hand, of dimension or width 90 to 100 mm;
the reference line can have a total diameter of the order of 5 mm; each measurement electrode can have a width of the order of 50 mm;
the relative permittivity of the spacing means (for example a hollow rigid plastic piece) can be 1.5; and
the maximum distance Dₘₐₓ, determined starting from the dimension of the measurement electrodes 108 and from the minimum detectable capacitance Cₘᵢₙ, as described above, can be of the order of 100 mm.

Under these conditions, Dₘᵢₙ=15 mm is obtained.

Thus, by positioning an electric line 202 of diameter less than or equal to that of the reference line (5 mm) in an interval of distances between Dₘᵢₙ=15 mm and Dₘₐₓ=100 mm of the measurement electrodes 108, this electric line 202 is both not “seen” by the measurement electrodes 108 (which it therefore does not interfere with), and positioned in the detection zone 126 of the device, so that an approaching object 124 can be detected before entering into contact with this electric line 202. Thus, the safety function of the collision detection is maintained despite the presence of the electric line 202, and also with respect to this electric line 202.

Of course, it may be desirable to define an interval in order to position the electric line contained in the interval (Dₘᵢₙ; Dₘₐₓ), but distant from the boundaries thereof. It is possible for example to define a positioning interval of amplitude half or a quarter of the interval (Dₘᵢₙ; Dₘₐₓ), positioned around the middle of the interval (Dₘᵢₙ; Dₘₐₓ), or around another position. It is thus possible to optimize both the absence of detection of the cable 202 and the detection of objects 124 beyond this cable.

In the example in FIG. 2, the spacing means 204 have the form of a support that extends between the surface of the device 200 comprising the measurement electrodes 108 and the electric line 202. The support 204 does not extend significantly beyond the electric line 202, seen from the appliance 200.

This support 204 can for example be produced in a rigid plastic material, with a hollow structure in order to maximize the volume of included air.

The support 204 is fixed to the surface of the appliance 200 comprising the measurement electrodes 108, optionally above the measurement electrodes 108, for example by a collar, preferably dielectric, or by any other known fixing means of the screwing, bonding etc. type.

The electric line 202 is fixed to the support 204 for example by a collar, or a strap, or by any other means.

FIG. 3 is a diagrammatic representation of another non-limitative embodiment of a spacing means that can be utilized in an appliance according to the invention.

The appliance represented in FIG. 3 is the appliance 200 in FIG. 2.

Unlike in FIG. 2, in FIG. 3, the appliance 200 comprises a spacing means produced by a support 302 that extends beyond the electric line 202. In other words, the support 302 does not stop at the electric line 202.

The support 302 comprises a pass-through opening 304 in which the cable 202 is passed. The pass-through opening 304 can be closed. Alternatively, the pass-through opening 304 can be open, for example on the support side 302 or at a free end of said support 302, to position the electric line 202 there.

The support 302 is fixed to the surface of the appliance 200 comprising the measurement electrodes 108, for example by a collar, preferably dielectric, or by bonding.

The support 302 is preferably produced in a flexible and elastic material, for example from foam, intended to crush if an object 124 comes into pressing contact on its end face opposite the measurement electrodes 108. Thus, the presence of a potentially damaging element on the appliance 200 is avoided.

Moreover, and in particular if the support 302 extends beyond the detection zone 126, it can be arranged so that, in the case of pressure or crushing, the cable 202 moves towards the measurement electrodes 108 to a distance which allows its detection by these electrodes 108, which makes it possible to detect the presence of an object even beyond the detection zone 126.

FIG. 4 is a diagrammatic representation of another non-limitative embodiment of a spacing means that can be utilized in an appliance according to the invention.

The appliance represented in FIG. 4 is the appliance 200 in FIG. 2.

Unlike in FIG. 2, in FIG. 4, the appliance 200 comprises a spacing means produced by a spacer 402 which is fixed to the electric line 202, and no longer to the surface of the appliance 200 comprising the measurement electrodes 108.

The spacer 402 extends on either side of the electric line 202 symmetrically or non-symmetrically.

The spacer 402 comprises a pass-through opening 404 in which the cable 202 is passed. The pass-through opening 404 can be closed. Alternatively, the pass-through opening 404 can be open, for example on the spacer side 402 or at a free end of the spacer 402, to position the electric line 202 there.

The spacer 402 can be fixed, or mobile, along the electric line 202.

The spacer can be produced, for example:
in the form of a rigid or flexible case, placed around the cable 202 and which traps a volume of air or gas;
in the form on an inflatable element;
from foam; or
in the form of a cylindrical brush with radial bristles.

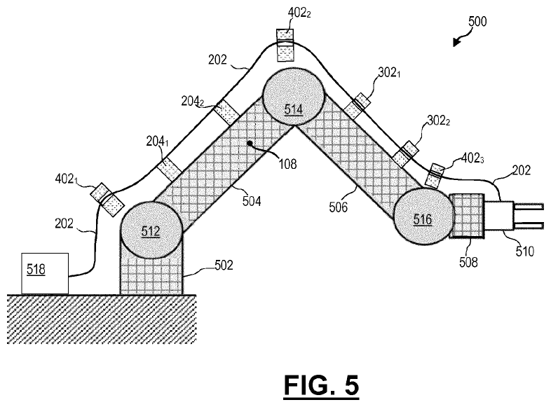

FIG. 5 is a diagrammatic representation of another non-limitative embodiment of an appliance according to the invention.

The appliance 500, represented in FIG. 5, is a robot and in particular a robotized arm such as an industrial collaborative robot working under the supervision of, or in collaboration with, an operator, or also a medical robot in the case of a surgical operation on the body of a person, or also a personal assistance robot.

The robotized arm 500 comprises a fixed segment 502, three articulated segments 504-508 and a functional head 510 fixed to the articulated segment 508. The functional head 510 is a gripper equipped with an electric motor (not shown).

The robotized arm 500 comprises three articulations 512-514, in particular motorized, making it possible to orientate the segments 504-508 according to the configuration sought.

Each segment 502-508 is equipped with measurement electrodes 108 in order to carry out a capacitive detection of objects located in the environment of the robot 500, in particular placed in/on the outer case of said segment.

The robotized arm 500 comprises an electric line, such as for example the electric line 202, in order to supply power to the functional head 510 and/or in order to communicate with the functional head 510 and a power supply and/or communication module 518 connected to the line 202.

The robotized arm 500 comprises, at the level of the segment 504, two spacing supports 204₁ and 204₂, fixed to the segment 504, in order to separate the electric line 202 from the measurement electrodes 108 placed on this segment 504. Each of the spacing supports 204₁ and 204₂ can be the spacing support 204 in FIG. 2.

The robotized arm 500 comprises, at the level of the segment 506, two spacing supports 302₁ and 302₂, fixed to the segment 506, in order to separate the electric line 202 from the measurement electrodes 108 placed on this segment 506. Each of the spacing supports 302₁ and 302₂ can be the spacing support 302 in FIG. 3.

The robotized arm 500 comprises, at the level of each articulation 512-516, a spacer, respectively 402₁, 402₂ et 402₃, fixed to the electric line 202, in order to separate the electric line 202 from the measurement electrodes 108 placed on the robotized arm 500. Each of the spacers 402₁, 402₃ and 402₃ can be the spacer 402 in FIG. 4.

Of course, the invention is not limited to the examples which have just been described and numerous adjustments can be made to these examples without exceeding the scope of the invention.

1. An appliance comprising:
at least one electrode, called measurement electrode, polarized at an alternating electrical potential (V_{G}), called detection electrical potential, different from a ground potential, at a frequency, called detection frequency, in order to detect at least one object in a detection zone;
at least one capacitive detection electronics, connected to said measurement electrodes, in order to detect a signal with respect to a capacitive coupling between said object and at least one measurement electrode, and
an electric line comprising at least one electric wire, in said detection zone;
said appliance also comprising at least one spacing means for distancing said electric line in order to position it at a distance from the at least one measurement electrode comprised between:
a distance (Dₘᵢₙ), called minimum distance, corresponding to the distance beyond which an electric line, called reference electric line, with a predetermined dimension, generates a coupling capacitance with the at least one measurement electrode, less than a predetermined threshold capacitance; and
a distance (Dₘₐₓ), called maximum distance, corresponding to the distance beyond which an object, called reference object, with a predetermined dimension, greater than the dimension of said reference electric line, generates a coupling capacitance with the at least one measurement electrode, less than said threshold capacitance.

2. The appliance according to claim 1, characterized in that the threshold capacitance is determined by taking account of:
a capacitance detection limit, dependent on a detection noise level of the capacitive detection electronics; and/or
an infinite capacitance, as measured by the capacitive detection electronics in the absence of an object or electric line.

3. The appliance according to claim 1, characterized in that the dimension of the reference electric line corresponds to a total diameter of the conductors of said reference line.

4. The appliance according to claim 1, characterized in that the dimension of the reference object corresponds to:
a width or a length of the reference object; or
a width or a length of a reference object of the same width or the same length as the at least one measurement electrode.

5. The appliance according to claim 1, characterized in that the minimum distance (Dₘᵢₙ) and the maximum distance (Dₘₐₓ) verify the following relationship:
$${D}_{min} = \frac{{ɛ}_{r} {L}_{c}}{{L}_{o}} {D}_{max}$$
with:
Dₘᵢₙ the minimum distance,
Dₘₐₓ the maximum distance,
εᵣ the overall relative permittivity of the spacing means,
L_{c} the dimension of the reference electric line, and
Lₒ the dimension of the reference object.

6. The appliance according to claim 1, characterized in that at least one spacing means has an overall relative dielectric permittivity less than or equal to 2, in particular 1.5.

7. The appliance according to claim 1, characterized in that at least one spacing means is fixed to a surface of said appliance, in particular to an outer surface of said appliance.

8. The appliance according to claim 1, characterized in that at least one spacing means is fixed to the electric line.

9. The appliance according to claim 1, characterized in that at least one spacing means is flexible and extends beyond the electric line, seen from the at least one measurement electrode.

10. The appliance according to claim 1, characterized in that at least one spacing means is inflatable, and/or has the form of a cylindrical brush with radial bristles, and/or at least partly hollow, or spongy, or in the form of a foam.

11. The appliance according to claim 1, characterized in that it comprises at least one electrode, called guard electrode, arranged on the side opposite the detection zone with respect to the measurement electrodes, and polarized at a potential, called guard potential (V_{G}), that is identical to the detection potential at the detection frequency.

12. The appliance according to claim 1, characterized in that the electric line is a line for the electric power supply of, and/or for control of, and/or for communication with, an electric component part of said appliance.

13. The appliance according to claim 1, characterized in that it is a robot in one of the following forms: robotized arm, mobile robot, vehicle on wheels or tracks, robot of the humanoid, or gynoid, or android type.

14. The appliance according to claim 13, characterized in that it is a robot comprising at least two segments connected together by an articulation, said appliance comprising at least one spacing means at said articulation.
